(19) United States
(12) Patent Application Publication
(10) Pub. No.: US 2026/0206165 A1
(43) Pub. Date: Jul. 16, 2026

(54) POWER CONVERSION DEVICE

(71) Applicant: LG INNOTEK CO., LTD., Seoul (KR)

(72) Inventors: Ji Hwan JEON, Seoul (KR); Dong Keun YOON, Seoul (KR); Jae Yeop JUNG, Seoul (KR)

(73) Assignee: LG INNOTEK CO., LTD., Seoul (KR)

(21) Appl. No.: 19/134,174

(22) PCT Filed: Nov. 30, 2023
(86) PCT No.: PCT/KR2023/019614

§ 371 Date: May 29, 2025

(30) Foreign Application Priority Data
Nov. 30, 2022 (KR) 10-2022-0165157

(51) Int. Cl. H05K 7/14; H05K 1/18

(52) U.S. Cl. CPC H05K 7/1432; H05K 1/18; H05K 2201/10189; H05K 2201/10356

(57) ABSTRACT

A power conversion device comprises: a housing; a printed circuit board disposed within the housing; an electronic component module including a core and a plurality of cables being extended from the core; and a connector disposed on one side of the printed circuit board and to which one end of a cable is coupled, wherein each of the plurality of cables has a cable terminal including a first hole disposed at one end thereof, and wherein the connector includes: a first region including a plurality of cable coupling grooves such that the plurality of cables are separately coupled to each other; and a second region including a coupling portion for coupling the cable terminal, and a coupling groove formed in the coupling portion.

### TECHNICAL FIELD

The present embodiment relates to a power conversion device.

### BACKGROUND ART

Recently, countries around the world are making various attempts to replace existing fossil fuel resources. First of all, we are making intensive investments in the renewable energy industry and the energy distribution and storage industry to enhance energy efficiency for the use of eco-friendly energy. In the wake of the suspension of nuclear power plant use and power outages caused by earthquakes in Japan, so domestically, various policies for the energy industry are planned and underway. Given this trend, not only is the demand for renewable energy increased, but technology for efficiently managing power, such as smart grids, is also being actively studied

The problem of using energy efficiently leads to analysis of demand patterns of users, such as location and time, and distributing energy produced by considering users'demand patterns is the core concept of the smart grid.

Therefore, in order to store the produced energy for a certain period of time or space and supply it according to the user's usage pattern, a storage device, that is, a battery, where the produced energy can stay is required, and the concept of an extended version of these batteries is called an energy storage system (ESS).

An energy storage system (ESS) is an energy storage system that controls various voltages/currents generated from distributed power or renewable energy to be connected to the power system as needed or to store and use idle energy. A power conversion system (PCS) is a system that converts characteristics of electricity, such as AC/DC, voltage, and frequency, to receive power from a power source in an energy storage system (ESS) and store it in a battery or to discharge it to a system.

The power conversion device has an outer shape formed by a housing, and a plurality of electronic components for driving the power conversion device are disposed inside the housing. The plurality of electronic components is electrically connected to one another. For example, the plurality of electronic components may be interconnected through wiring. According to the structure as described above, it is difficult to arrange the electronic components considering electrical connection within a narrow space inside the housing.

### DETAILED DESCRIPTION OF THE INVENTION

### Technical Subject

The present embodiment is intended to provide a power conversion device that can compactly connect a plurality of electronic components and enhance the efficiency of assemblability.

### Technical Solution

A power conversion device according to the present embodiment comprises: a housing; a printed circuit board being disposed inside the housing; an electronic component module including a core and a plurality of cables being extended from the core; and a connector being disposed on one surface of the printed circuit board and to which one end of a cable is coupled, wherein a cable terminal including a first hole is disposed at one end of each of the plurality of cables, and wherein the connector includes: a first region including a plurality of cable coupling grooves so that the plurality of cables is separately coupled to one another; and a second region including a coupling portion and a coupling groove being formed inside the coupling portion so that the cable terminals are coupled.

The connector includes a holder, and multiple guide portions being protruded upward are formed on an upper surface of the holder corresponding to the first region, and the cable coupling groove can be disposed between the multiple guide portions.

The cable coupling groove may have a region bent at least once.

A guide protrusion for supporting the cable is formed on a side surface of the guide portion, and the guide protrusion can be respectively formed on one side surface of the guide portion and one side surface of an adjacent guide portion, with respect to the single cable coupling groove.

A covering region having a shape with a larger cross-sectional area than other regions may be disposed on an outer surface of the cable adjacent to the cable terminal, and an extension portion having a larger width than other regions and to which the covering region is coupled may be disposed at one end of the cable coupling groove facing the second region.

A plurality of coupling portions is provided corresponding to the number of cables, and the plurality of coupling portions can be disposed in a zigzag shape.

It includes a connection region connecting the first region and the second region, wherein the second region may be flexibly supported against the first region with respect to the connection region.

It includes a protruded portion being protruded from the bottom surface, wherein the protruded portion includes a groove, and wherein a fastening portion being coupled to the groove and in contact with the cable terminal may be included.

The fastening portion includes a body being coupled to the groove and a flange being extended outwardly from an upper end of the body, and an upper surface of the flange may come into contact with a lower surface of the cable terminal.

A screw hole may be formed on an upper surface of the body so that a screw can be screw-coupled thereto.

### Advantageous Effects

Through the present embodiment there is an advantage in that miniaturization becomes possible by disposing multiple cores with different functions inside a single module.

In particular, since multiple cables being extended from each of the multiple cores are extended in different directions through a first guide and a second guide, there is an advantage in that different cables inside the module can be easily aligned with one another.

In addition, there is an advantage in that durability can be enhanced due to the fixing structure of the core and cable through a molding part.

In addition, there is an advantage in that the cables can be easily aligned inside the housing, preventing multiple cables inside the device from becoming entangled or twisted through the connector.

In particular, due to the buried structure through the cable coupling groove inside the connector, it has the advantage of enhancing the assemblability and preventing the cable from being protruded into other regions inside the housing.

In addition, there is an advantage in that the bonding force can be maintained more firmly in the electrical connection region due to the increased contact area and the coupling structure among the cable terminal, fastening portion, and terminal portion that takes tension into account.

### BRIEF DESCRIPTION OF DRAWINGS

FIG. 1 is a perspective view illustrating an outer appearance of a power conversion device according to an embodiment of the present invention.

FIG. 2 is a plan view illustrating an upper surface of a power conversion device according to an embodiment of the present invention.

FIG. 3 is a plan view illustrating a side surface of a power conversion device according to an embodiment of the present invention.

FIG. 4 is a plan view illustrating a lower surface of a power conversion device according to an embodiment of the present invention.

FIG. 5 is an exploded perspective view of a power conversion device according to an embodiment of the present invention.

FIG. 6 is a view illustrating FIG. 5 from a different angle.

FIG. 7 is a view illustrating FIG. 2 excluding a printed circuit board.

FIG. 8 is a perspective view illustrating an outer appearance of an electronic component module according to an embodiment of the present invention.

FIG. 9 is a view illustrating FIG. 8 from a different angle.

FIG. 10 is a plan view illustrating an upper surface of an electronic component module according to an embodiment of the present invention.

FIG. 11 is a view illustrating a coupling structure of a plurality of cores in a bracket according to an embodiment of the present invention.

FIG. 12 is a view illustrating a coupling structure of a bracket, a first guide, and a second guide according to an embodiment of the present invention.

FIG. 13 is an exploded perspective view of an electronic component module according to an embodiment of the present invention.

FIG. 14 is a perspective view of a bracket according to an embodiment of the present invention.

FIG. 15 is a view illustrating a coupling structure of a first guide and a first cable according to an embodiment of the present invention.

FIG. 16 is a plan view illustrating a coupling structure of an electronic component module and a connector inside a housing according to an embodiment of the present invention.

FIG. 17 is a view illustrating A-A′ of FIG. 16.

FIG. 18 is a perspective view illustrating an outer appearance of a connector according to an embodiment of the present invention.

FIG. 19 is a view illustrating FIG. 18 from a different angle.

FIG. 20 is a plan view illustrating an upper surface of a connector according to an embodiment of the present invention.

FIG. 21 is a drawing illustrating B-B′ of FIG. 20.

FIG. 22 is a perspective view illustrating a coupling structure of a connector and a first cable according to an embodiment of the present invention.

FIG. 23 is a drawing illustrating a coupling structure of a first terminal in a connector according to an embodiment of the present invention.

FIG. 24 is a cross-sectional view illustrating a coupling structure of a printed circuit board, a connector, and a first terminal according to an embodiment of the present invention.

### BEST MODE

Hereinafter, preferred embodiments of the present invention will be described in detail with reference to the accompanying drawings.

However, the technical idea of the present invention is not limited to some embodiments to be described, but may be implemented in various forms, and inside the scope of the technical idea of the present invention, one or more of the constituent elements may be selectively combined or substituted between embodiments.

In addition, the terms (including technical and scientific terms) used in the embodiments of the present invention, unless explicitly defined and described, can be interpreted as a meaning that can be generally understood by a person skilled in the art, and commonly used terms such as terms defined in the dictionary may be interpreted in consideration of the meaning of the context of the related technology.

In addition, terms used in the present specification are for describing embodiments and are not intended to limit the present invention.

In the present specification, the singular form may include the plural form unless specifically stated in the phrase, and when described as “at least one (or more than one) of A and B and C”, it may include one or more of all combinations that can be combined with A, B, and C.

In addition, in describing the components of the embodiment of the present invention, terms such as first, second, A, B, (a), and (b) may be used. These terms are merely intended to distinguish the components from other components, and the terms do not limit the nature, order or sequence of the components.

And, when a component is described as being ‘connected’, ‘coupled’ or ‘interconnected’ to another component, the component is not only directly connected, coupled or interconnected to the other component, but may also include cases of being ‘connected’, ‘coupled’, or ‘interconnected’ due that another component between that other components.

In addition, when described as being formed or disposed in “on (above)” or “below (under)” of each component, “on (above)” or “below (under)” means that it includes not only the case where the two components are directly in contact with, but also the case where one or more other components are formed or disposed between the two components. In addition, when expressed as “on (above)” or “below (under)”, the meaning of not only an upward direction but also a downward direction with respect to one component may be included.

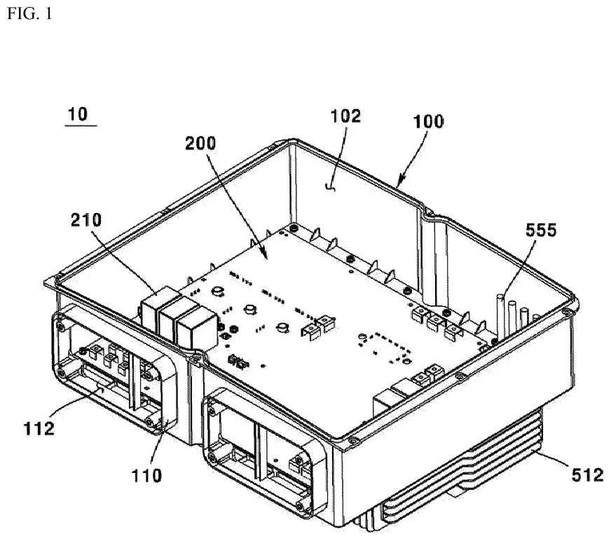

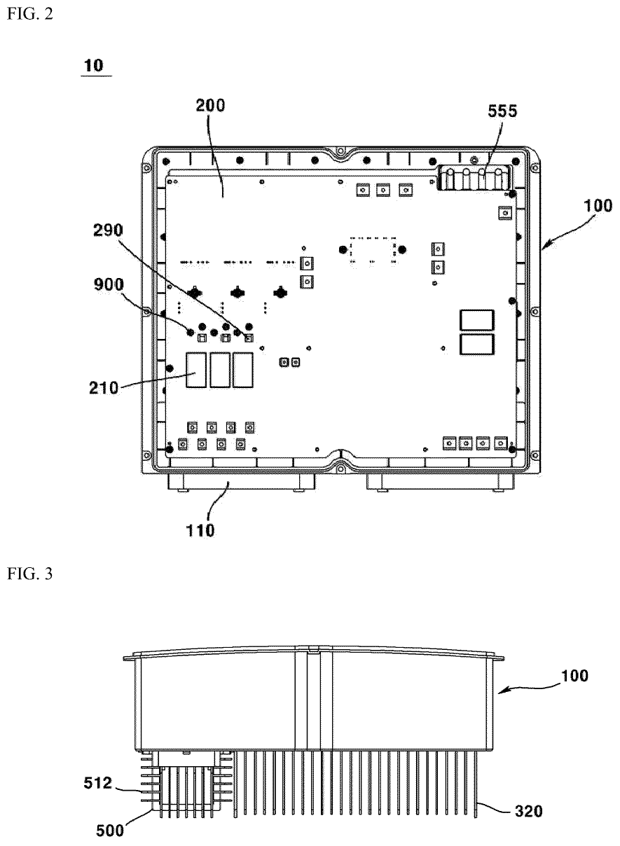

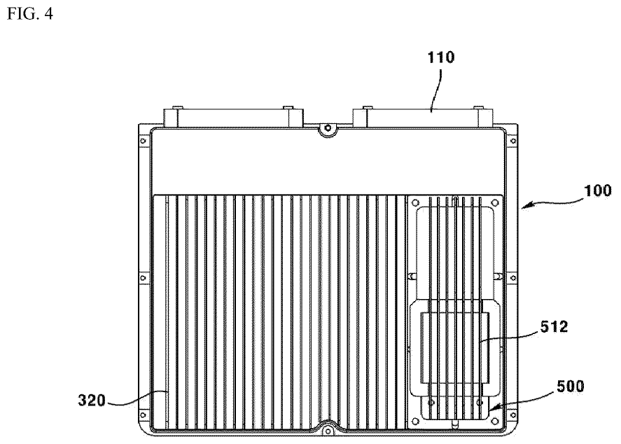

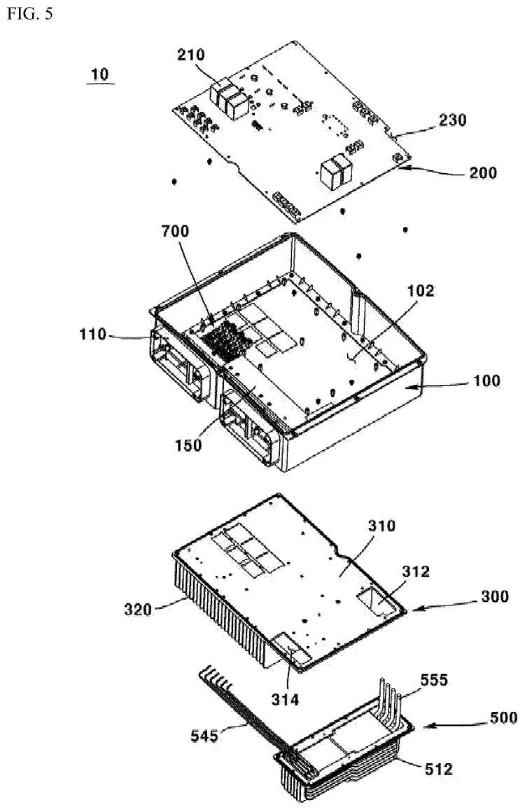

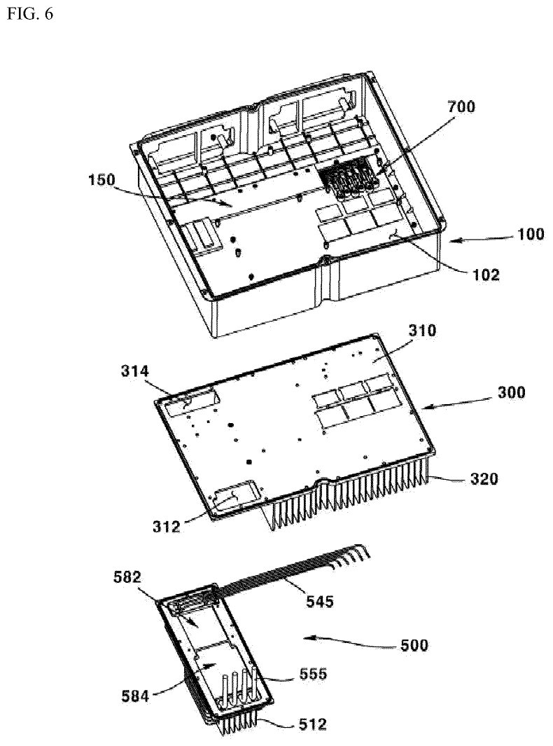

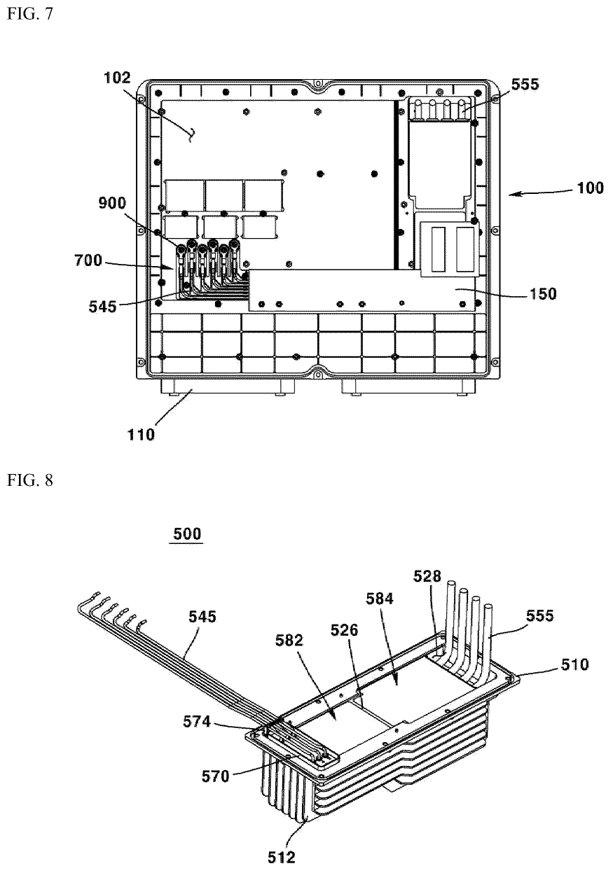

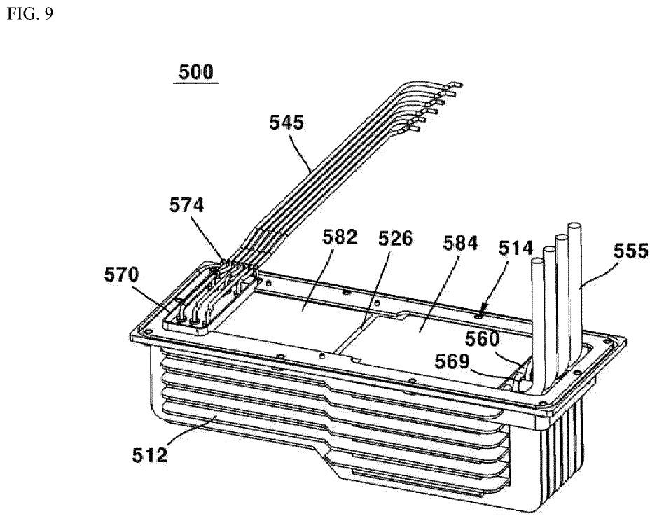

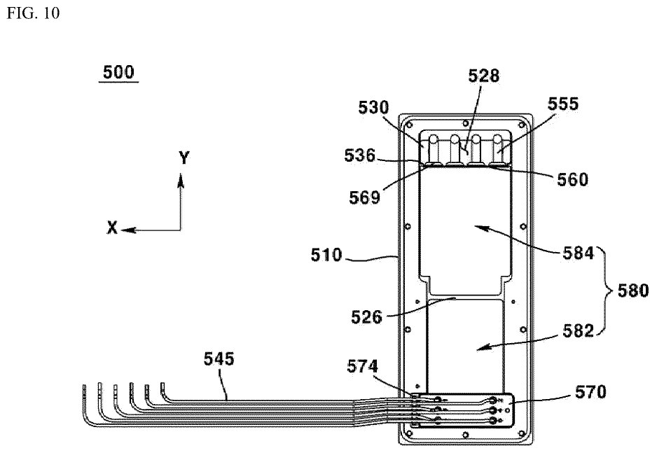

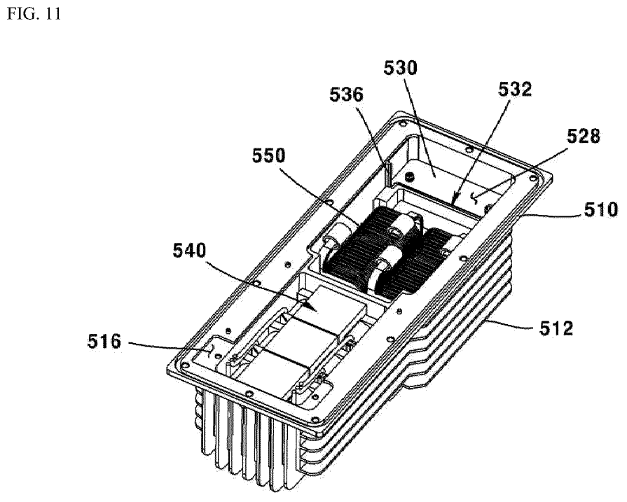

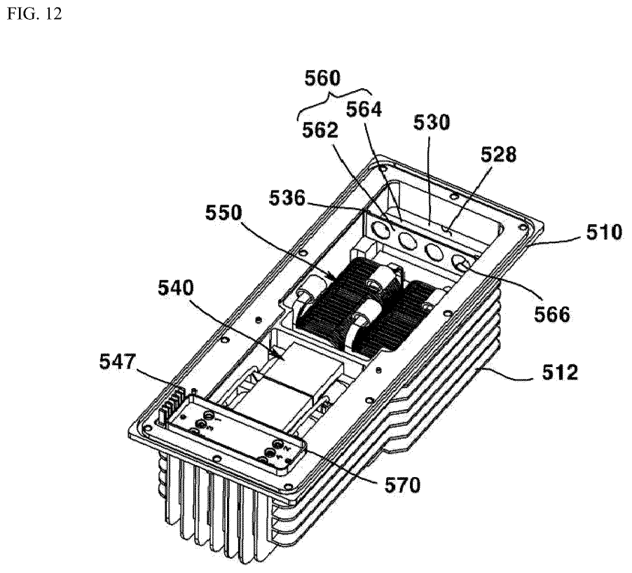

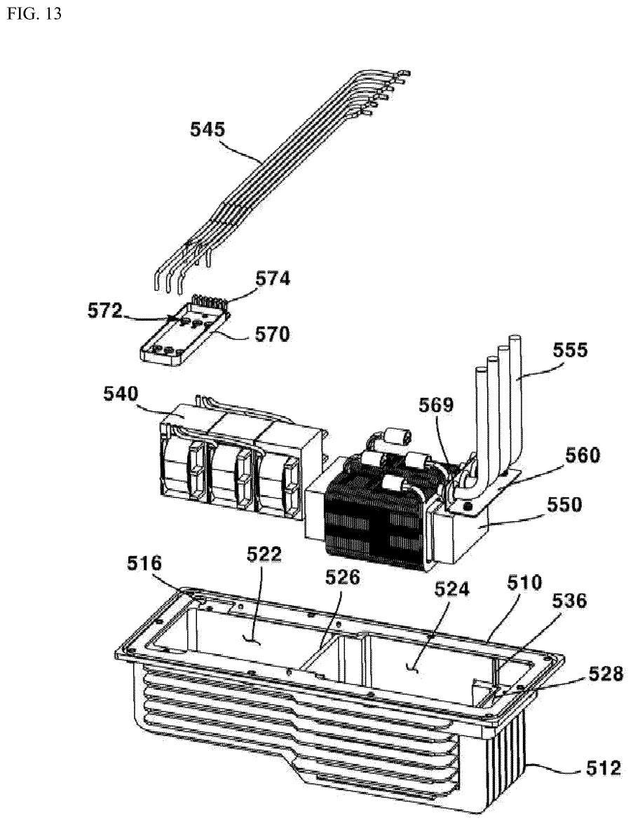

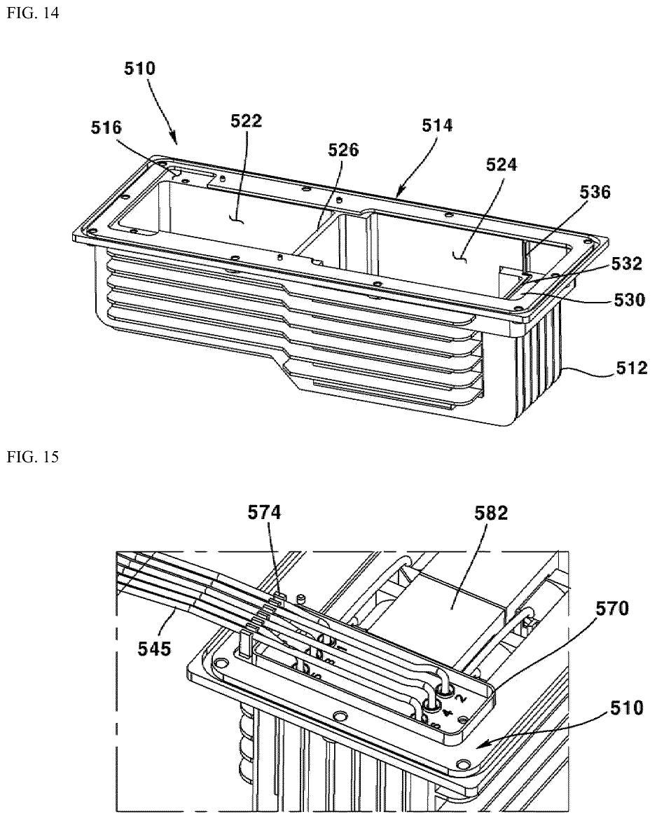

FIG. 1 is a perspective view illustrating an outer appearance of a power conversion device according to an embodiment of the present invention; FIG. 2 is a plan view illustrating an upper surface of a power conversion device according to an embodiment of the present invention; FIG. 3 is a plan view illustrating a side surface of a power conversion device according to an embodiment of the present invention; FIG. 4 is a plan view illustrating a lower surface of a power conversion device according to an embodiment of the present invention; FIG. 5 is an exploded perspective view of a power conversion device according to an embodiment of the present invention; FIG. 6 is a view illustrating FIG. 5 from a different angle; FIG. 7 is a view illustrating FIG. 2 excluding a printed circuit board; FIG. 8 is a perspective view illustrating an outer appearance of an electronic component module according to an embodiment of the present invention; FIG. 9 is a view illustrating FIG. 8 from a different angle; FIG. 10 is a plan view illustrating an upper surface of an electronic component module according to an embodiment of the present invention; FIG. 11 is a view illustrating a coupling structure of a plurality of cores in a bracket according to an embodiment of the present invention; FIG. 12 is a view illustrating a coupling structure of a bracket, a first guide, and a second guide according to an embodiment of the present invention; FIG. 13 is an exploded perspective view of an electronic component module according to an embodiment of the present invention; FIG. 14 is a perspective view of a bracket according to an embodiment of the present invention; and FIG. 15 is a view illustrating a coupling structure of a first guide and a first cable according to an embodiment of the present invention.

Referring to FIGS. 1 to 7, a power conversion device 10 according to an embodiment of the present invention may include a housing 100, a printed circuit board 200, a cover 300, and an electronic component module 500.

The housing 100 may be formed in a box shape with an open upper surface. A space 102 may be formed inside the housing 100 so that the printed circuit board 200 and the electronic component module 500 may be disposed. An upper surface of the space 102 may be opened upward. A separate cover (not shown) may be provided on an upper surface of the housing 100 so that the upper surface of the space 102 can be covered.

A connector coupling portion 110 may be disposed on a side surface of the housing 100. A hole 112 may be formed in the connector coupling portion 110 so that a connector (not shown) for coupling with an external terminal may be disposed. The connector coupling portion 110 may be provided in multiple numbers. Through the connection of the connector and the external terminal, power may be provided to the power conversion device 10, or power converted by the power conversion device 10 may be provided to the external terminal.

The housing 100 can be formed of metal or plastic material.

The housing 100 may include a bottom plate and a plurality of side plates. An upper surface of the bottom plate may form a bottom surface of the space 102. The side plates may be disposed to be extended upward from an edge of the bottom plate and may form a side surface of the power conversion device. The bottom plate may be omitted. In this case, an upper surface of the cover 300 may be disposed to form a bottom surface of the space 102.

The printed circuit board 200 may be disposed in the space 102. A plurality of electronic components 210 for driving the power conversion device 10 may be disposed on a surface of the printed circuit board 200. For example, a micro controller unit (MCU) element or a plurality of switching elements for controlling the power conversion device 10 may be disposed on an upper surface or a lower surface of the printed circuit board 200.

The printed circuit board 200 may have a rectangular cross-sectional shape. The printed circuit board 200 may be disposed on the upper side of the cover 300 and the electronic component module 500. A spacer or guide for fixing the printed circuit board 200 may be disposed on an inner surface of the housing 100. A lower surface of the printed circuit board 200 may be disposed at a predetermined distance from a bottom surface of the space 102.

The printed circuit board 200 may include a cable hole 230. The cable hole 230 may have a shape that penetrates from an upper surface to a lower surface of the printed circuit board 200. The cable hole 230 may be disposed at one corner of the printed circuit board 200. A second cable 555, which will be described later, may be disposed to penetrate the cable hole 230.

The printed circuit board 200 may include an assembly hole 290 (see FIG. 2). The assembly hole 290 may be disposed adjacent to a fastening member 900, which will be described later. The assembly hole 290 may be disposed adjacent to one corner of the printed circuit board 200 opposite to the other corner where the cable hole 230 is formed, with respect to the center of the printed circuit board 200. The assembly hole 290 may have a rectangular cross-sectional shape. Through the assembly hole 290, a worker may check the coupling state of the fastening member 900 to be described later and the connector 700 during the assembling process of the power conversion device 10. The assembly holes 290 may be provided in multiple numbers and disposed to be spaced apart from one another.

The cover 300 may be disposed at a lower portion of the housing 100. The cover 300 may be coupled to the lower surface of the housing 100. The cover 300 may be coupled to a bottom plate of the housing 100. The cover 300 and the lower surface of the housing 100 may be screw-coupled. As described above, the bottom plate may be omitted. In this case, an upper surface of the cover 300 may form a bottom surface of the space 102.

The cover 300 may include a bottom plate 310 and a first heat dissipation fin 320. The bottom plate 310 may be coupled to a lower surface of the housing 100. The cross-sectional shape of the bottom plate 310 may be formed to correspond to the cross-sectional shape of the space 102. A first hole 314 and a second hole 312 may be formed in the bottom plate 310. The first hole 314 and the second hole 312 may each have a shape penetrating from an upper surface to a lower surface of the bottom plate 310. The first hole 314 and the second hole 312 may be disposed to be spaced apart from each other. The first hole 314 and the second hole 312 may be spaced apart from each other in a first direction. At least a portion of a first cable 545 to be described later may be disposed in the first hole 314. The first cable 545 may be disposed so as to penetrate through the first hole 314. At least a portion of a second cable 555 to be described later may be disposed in the second hole 312. The second cable 555 may be disposed so as to penetrate through the second hole 312.

The first heat dissipation fin 320 may be shaped to be protruded downward from a lower surface of the bottom plate 310. Since the cross-sectional area of the cover 300 is increased through the first heat dissipation fin 320, there is an advantage in that heat in the space 102 inside the housing 100 can be easily dissipated. The first heat dissipation fin 320 may be provided in plurality and may be disposed to be spaced apart from each other in a second direction perpendicular to the first direction. The first heat dissipation fin 320 may be disposed to be overlapped with at least a portion of the printed circuit board 200 in an up and down direction.

The electronic component module 500 may be disposed on a lower surface of the housing 100. The electronic component module 500 may be disposed on a lower surface of the cover 300. The electronic component module 500 may be coupled to a lower surface of the bottom plate 310. The electronic component module 500 may include a plurality of inductors.

Hereinafter, the electronic component module 500 will be described in detail.

Referring to FIGS. 8 to 15, the electronic component module 500 may include a bracket 510, a first core 540, a second core 560, a first cable 545, a second cable 555, a first guide 570, a second guide 560, and a molding part 580.

The bracket 510 may form an outer shape of the electronic component module 500. The bracket 510 may be formed of a metal or plastic material. The bracket 510 may be coupled to a lower surface of the cover 300. In this case, the first heat dissipation fin 320 may not be formed on a lower surface of the cover 300 to which an upper surface of the bracket 510 is coupled. That is, the first heat dissipation fin 320 may be formed on a lower surface of the cover 300 except for the region where the electronic component module 500 is coupled.

The bracket 510 may be formed in a box shape with an open upper surface. The bracket 510 may include a lower plate forming a lower surface, and a side plate being extended upward from an edge of the lower plate. At least a portion of the side plate may be disposed to be overlapped with the first heat dissipation fins 320 in a horizontal direction. A plurality of second heat dissipation fins 512 being protruded outward may be formed on an outer surface of the bracket 510. Since the outer surface cross-sectional area of the bracket 510 is increased by the second heat dissipation fins 512, heat dissipation efficiency may be enhanced. The second heat dissipation fins 512 may have a shape being protruded outward from an outer surface of the side plate and an outer surface of the lower plate. In this case, the second heat dissipation fin 512 being protruded from an outer surface of the side plate and the second heat dissipation fin 512 being protruded from an outer surface of the lower plate can be disposed perpendicular to each other.

A space may be formed inside the bracket 510 in which the first core 540 and the second core 560 are disposed. The space may be a groove shape formed to be recessed downward from an upper surface of the bracket 510. The space may be disposed to be overlapped with the printed circuit board 200 in an up and down direction. The space may include a first groove 522 and a second groove 524. The first groove 522 and the second groove 524 may be disposed to be mutually separable with respect to the partition 526. The first groove 522 and the second groove 524 may be disposed to be spaced apart from each other with respect to the first direction. The partition 526 may have a shape being protruded upward from an upper surface of the lower plate. A bottom surface of the first groove 522 may be disposed higher than a bottom surface of the second groove 524.

A plurality of screw holes 514 may be formed on an upper surface of the bracket 510. An upper surface of the bracket 510 may be screw-coupled to a lower surface of the cover 300 through the screw holes 514. A plurality of protrusions may be formed on an upper surface of the bracket 510. A protrusion hole into which the plurality of protrusions is coupled is formed on a lower surface of the cover 300, so that the cover 300 and the bracket 510 may be mutually coupled.

A first guide coupling groove 516 may be formed on an upper surface of the bracket 510 so as to be recessed downward compared to other regions. The cross-sectional shape of the first guide coupling groove 516 may be formed to correspond to the cross-sectional shape of the first guide 570. The first guide coupling groove 516 may be disposed on an outer side of the first groove 522. The first guide coupling groove 516 may be disposed adjacent to one side end of the bracket 510.

The bracket 510 may include a third groove 528. The third groove 528 may be formed to be recessed downward from an upper surface of the bracket 510 compared to other regions. The first groove 522, the second groove 524, and the third groove 528 may be disposed adjacent to each other with respect to the first direction. The second groove 524 may be disposed between the first groove 522 and the third groove 528.

A bottom surface of the third groove 528 may be disposed higher than the bottom surfaces of the first groove 522 and the second groove 524. The bracket 510 may include a protruded portion 530 (see FIG. 14) being protruded upward from an upper surface of the lower plate, at least a portion of an upper surface forming the bottom surface of the third groove 528. The protruded portion 530 may be disposed adjacent to one side end of the bracket 510 and the other side end opposite to it. A plurality of regions being disposed in a stepwise manner in an up and down direction may be formed on an upper surface of the protruded portion 530. An upper surface of the protruded portion 530 includes a first step surface and a second step surface being disposed above the first step surface, and the first step surface can be disposed closer to the second groove 524 than the second step surface.

The bracket 510 may include a second guide support portion 536 (see FIG. 14). The second guide support portion 536 may be formed to be protruded inwardly from an inner surface of the third groove 528. The second guide support portion 536 may be provided in plurality and may be disposed to face each other in a second direction perpendicular to the first direction. The second guide support portions 536 may be formed to be extended in an up and down direction from an upper surface of the second step surface of the protruded portion 530 to an upper surface of the bracket 510. The second groove 524 and the third groove 528 may be mutually partitioned based on the second guide support portion 536. The second guide support portion 536 may support the second guide 560.

A guide groove 532 (see FIG. 14) being formed to be recessed downward compared to other regions may be formed on an upper surface of the protruded portion 530. The guide groove 532 may be formed so that both ends connect the lower ends of the plurality of second guide support portions 536. The guide groove 532 may have a cross-section that is approximately in the shape of the letter “⊂”. At least a portion of the second molding part 584 to be described later may be coupled into the guide groove 532.

The first core 540 may be coupled to the first groove 522. The first core 540 may include an inductor. The first core 540 may be a DC-DC core that converts a DC voltage into a DC voltage. The first core 540 may be provided in plurality and may be disposed adjacent to each other with respect to the first direction within the first groove 522. For example, the number of the first core 540 may be three.

The electronic component module 500 may include a first cable 545 being extended from the first core 540. The first cable 545 may be provided in multiples. For example, the number of the first cable 545 may be six, which is twice the number of the first cores 540. That is, with respect to a single first core 540, the number of the first cables 545 may be two. The first cable 545 may be connected at both ends to the first core 540 and the printed circuit board 200, so as to electrically connect the first core 540 and the printed circuit board 200 to each other.

The second core 560 may be coupled to the second groove 524. The second core 560 may include an inductor. The second core 560 may be a DC-AC core that converts a DC voltage into an AC voltage. The second core 560 may be provided in multiple numbers and may be disposed adjacently in the second direction inside the second groove 524. For example, the number of the second core 560 may be two.

The electronic component module 500 may include a second cable 555 being extended from the second core 560. The second cable 555 may be provided in multiple numbers. For example, the number of the second cables 555 may be four. That is, based on a single second core 560, the number of the second cable 555 may be two. The second cable 555 may have both ends connected to the second core 550 and the printed circuit board, respectively, to electrically connect the second core 550 and the printed circuit board 200 to each other. The cross-sectional area of the second cable 555 may be larger than the cross-sectional area of the first cable 545.

In the printed circuit board 200, the region where the first cable 545 is coupled and the region where the second cable 555 is coupled may be spaced apart from each other. For example, the region where the second cable 555 is coupled in the printed circuit board 200 may be disposed adjacent to one corner of the printed circuit board 200. The region where the first cable 545 is coupled in the printed circuit board 200 may be disposed at the other corner facing one corner of the printed circuit board 200. In this case, one corner of the printed circuit board 200 and the other corner of the printed circuit board 200 may not be adjacent. One corner of the printed circuit board 200 and the other corner of the printed circuit board 200 may be disposed to face each other with respect to the center of the printed circuit board 200.

The extended direction of the first cable 545 and the extended direction of the second cable 555 from the electronic component module 500 may be disposed to be perpendicular to each other. For example, referring to FIG. 10, the first cable 545 may be extended in an X-axis direction. In this case, the second cable 555 may be extended in a Z-axis direction, which is perpendicular to an X-axis and the Y-axis, that is, an upward direction of the electronic component module 500.

The first guide 570 may be coupled to an upper surface of the bracket 510. The first guide 570 may be positioned to be protruded upward from the cover 300 by penetrating the first hole 314 of the cover 300. A portion of the upper surface of the first core 540 may be covered by the first guide 570. The first guide 570 may align the first cable 545 on the electronic component module 500. The first guide 570 may be coupled to the first guide coupling groove 516. The upper surface of the first guide 570 may be protruded upward more than an upper surface of the bracket 510. The first guide 570 may be screw-coupled to an upper surface of the bracket 510.

The first guide 570 may include a plurality of first through holes 572 (see FIG. 13) penetrating from an upper surface to a lower surface. The first through hole 572 may be provided in plurality corresponding to the number of the first cable 545. For example, the number of the first through hole 572 may be six. The plurality of first through hole 572 may be disposed to be spaced apart from one another. For example, the plurality of first through hole 572 may be disposed in groups of three adjacent to each other in a first direction. The first cable 545 may be disposed to penetrate through the first through hole 572. A sealing member (not shown) may be disposed between an inner surface of the first through holes 572 and an outer surface of the first cable 545.

The first cable 545 being extended upward through the through hole 572 can be bent and extended in a second direction.

On an upper surface of the first guide 570, a first guide protrusion 574 being protruded upward from other regions may be disposed. The first guide protrusion 574 may be provided in multiple numbers and disposed to be spaced apart from one another along a first direction. Accordingly, a region where the first cable 545 is coupled may be formed between two adjacent first guide protrusions 574. When there are six first cables 545, seven first guide protrusions 574 may be provided to form six first cable 545 coupling regions. A catching part being protruded outward more than other regions is formed on a side surface of the first guide protrusion 574 forming a coupling region of the cable 545, thereby preventing the first cable 545 from being detached outward when the first cable 545 is coupled. The catching part may be disposed adjacent to an upper end of the first guide protrusion 574.

The second guide 560 may be disposed between the second groove 524 and the third groove 528. The second guide 560 may be coupled to an upper surface of the protruded portion 530. The second guide 560 may be screw-coupled to an upper surface of the protruded portion 530. The second guide 560 may align the second cable 555 on the electronic component module 500.

In detail, the second guide 560 may include a first plate portion 562 (see FIG. 12) and a second plate portion 564. The first plate portion 562 and the second plate portion 564 may be disposed perpendicular to each other. Due to the first plate portion 562 and the second plate portion 564, the second guide 560 may have a cross-section having an approximately “L” shape.

The first plate portion 562 may be positioned perpendicular to an upper surface of the bracket 510 or an upper surface of the protruded portion 530. The first plate portion 562 may have both ends supported by the second guide support portion 536. One side surface of the first plate portion 562 facing the third groove 528 may be in contact with the second guide support portion 536.

The first plate 562 may include a second through hole 566 penetrating from one side surface to the other surface. The second through hole 566 may be provided in multiple numbers corresponding to the number of the second cables 555. For example, the number of the second through hole 566 may be four. The plurality of second through hole 566 may be disposed to be spaced apart from each other along a second direction. The second cable 555 may be disposed to penetrate through the second through hole 566. A ring-shaped packing part 569 may be disposed between an inner surface of the second through hole 566 and an outer surface of the second cable 555. Accordingly, the connection state of the second cable 555 can be firmly maintained inside the second through hole 566, and external foreign substances can be prevented from entering through the second through hole 566. The second cable 555 protruded outwardly by penetrating through the second through hole 566 may be bent upward and extended. In this case, the second cable 555 may be disposed to penetrate the cable hole 230 of the printed circuit board 200. In addition, the second cable 555 may be disposed to penetrate the second hole 312 of the cover 300.

The second plate portion 564 may be formed to be extended horizontally from a lower end of the first plate portion 562. The second plate portion 564 may be screw-coupled to a bottom surface of the third groove 528. The second plate portion 564 may be disposed to cover the guide groove 532.

The molding part 580 may be formed in the first groove 522 and the second groove 524. The molding part 580 may be formed by injecting a molding solution into the first groove 522 and the second groove 524 and then curing the molding solution. Accordingly, the first core 540 and the second core 550 may be firmly fixed in the first groove 522 and the second groove 524, respectively. The molding part 580 may include a first molding part 582 disposed in the first groove 522 and a second molding part 584 disposed in the second groove 524. At least a portion of the second molding part 584 may be accommodated in the guide groove 532. The first molding part 582 can be coupled with the first guide 570. The second molding part 584 can be coupled with the second guide 560. Meanwhile, during the process of forming the second molding part 584, the first plate portion 562 can be prevented from being pushed in a first direction toward the third groove 528 by the support structure of the first plate portion 562 and the second guide support portion 536. In addition, the molding solution for forming the second molding part 584 can be prevented from flowing out by the packing part 569.

Meanwhile, in order to prevent electrical noise from occurring, a shielding member (not shown) may be disposed between an upper surface of the electronic component module 500 and a lower surface of the printed circuit board 200. The shielding member may be formed in a plate shape and may be disposed to be overlapped with the first core 540 and the second core 550 in an up and down direction.

According to the above structure, there is an advantage in that multiple cores with different functions can be disposed inside a single module, thereby enabling miniaturization.

In particular, since multiple cables being extended from each of the multiple cores are extended in different directions through the first guide and the second guide, there is an advantage in that different cables inside the module can be easily aligned with one another.

In addition, there is an advantage in that durability can be enhanced through the fixing structure of the core and cable through the molding part.

Hereinafter, the coupling structure of a printed circuit board 200 and an electronic component module 500 through a first cable 555 inside a power conversion device 10 according to the present embodiment will be described.

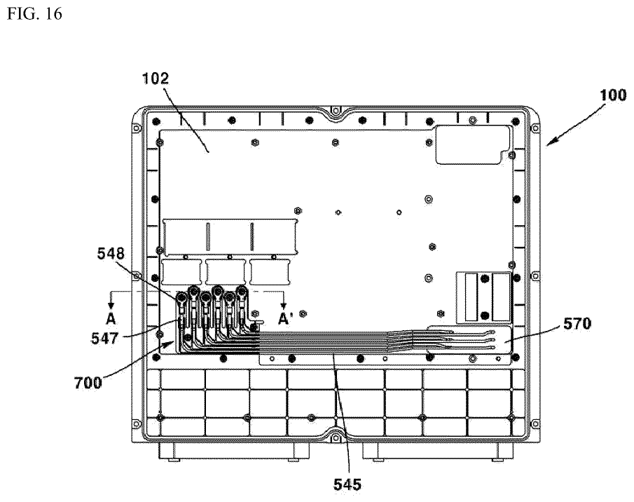

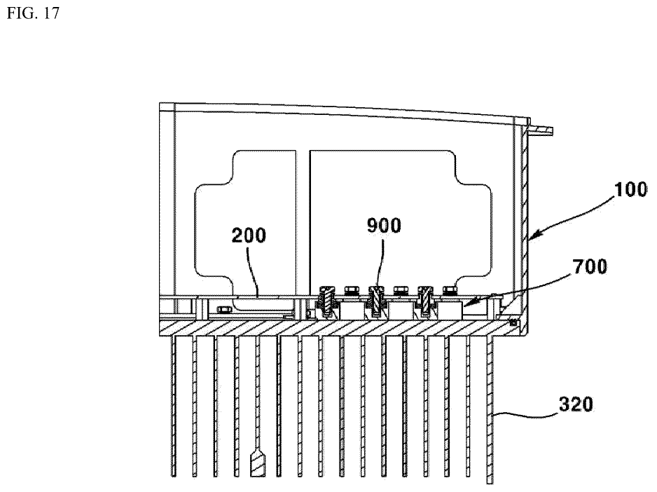

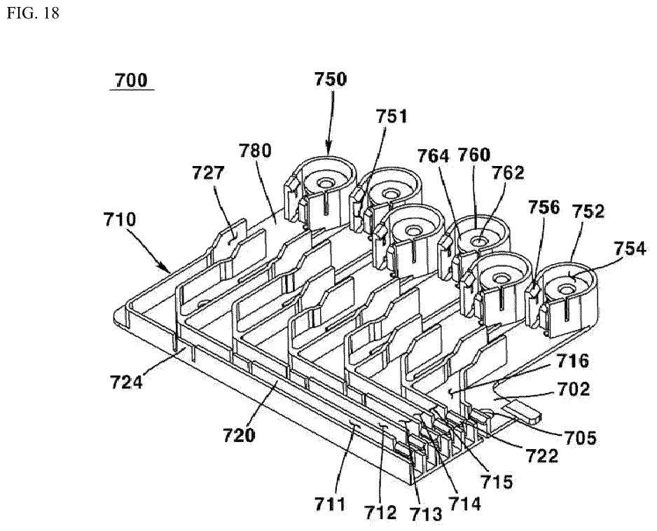

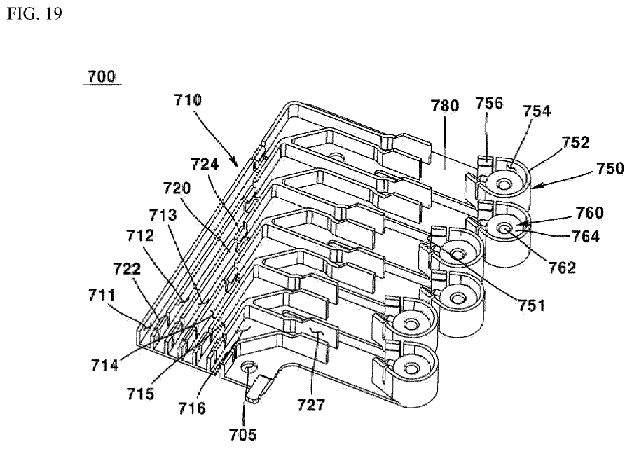

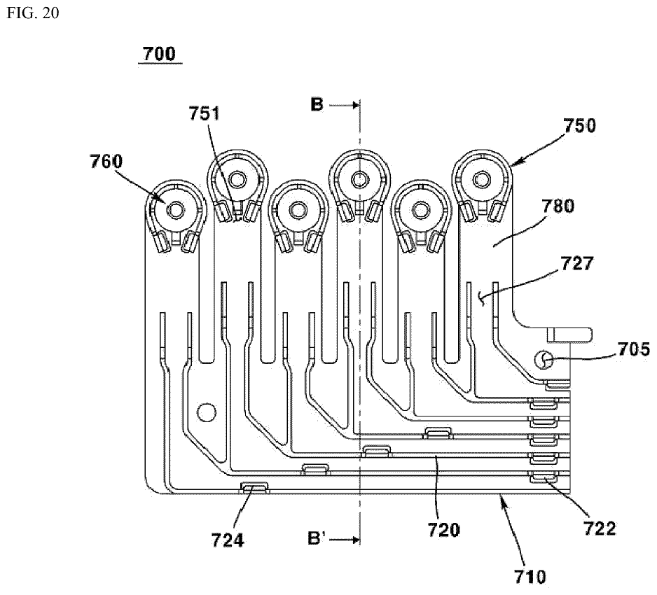

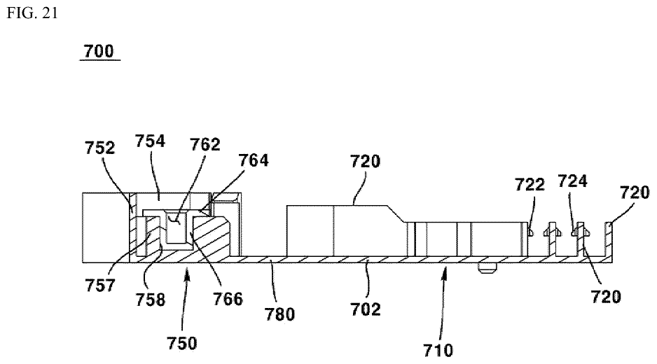

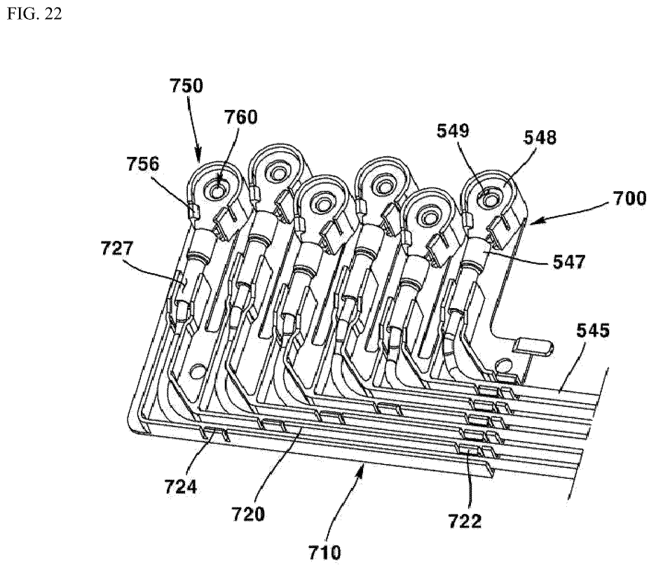

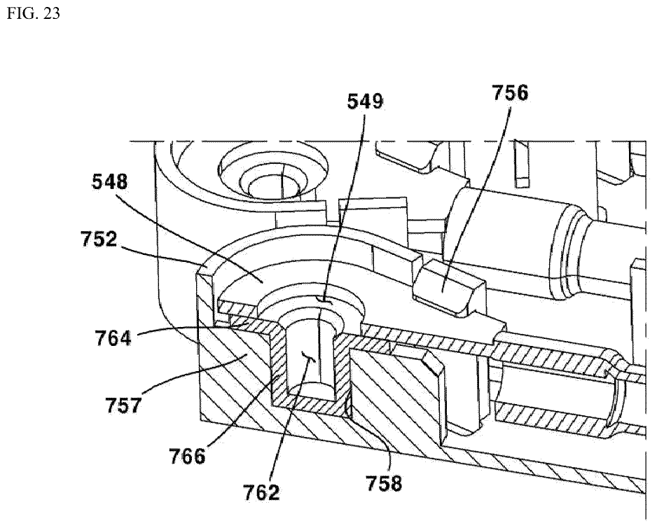

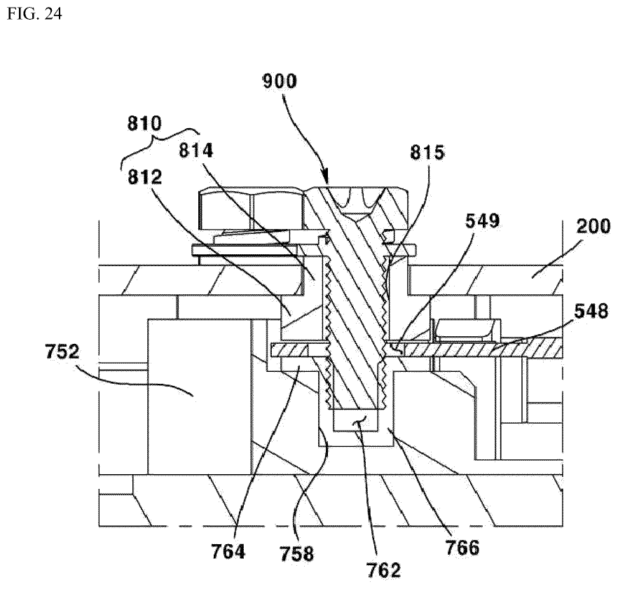

FIG. 16 is a plan view illustrating a coupling structure of an electronic component module and a connector inside a housing according to an embodiment of the present invention; FIG. 17 is a view illustrating A-A′ of FIG. 16; FIG. 18 is a perspective view illustrating an outer appearance of a connector according to an embodiment of the present invention; FIG. 19 is a view illustrating FIG. 18 from a different angle; FIG. 20 is a plan view illustrating an upper surface of a connector according to an embodiment of the present invention; FIG. 21 is a drawing illustrating B-B′ of FIG. 20; FIG. 22 is a perspective view illustrating a coupling structure of a connector and a first cable according to an embodiment of the present invention; FIG. 23 is a drawing illustrating a coupling structure of a first terminal in a connector according to an embodiment of the present invention; and FIG. 24 is a cross-sectional view illustrating a coupling structure of a printed circuit board, a connector, and a first terminal according to an embodiment of the present invention.

Referring to FIGS. 16 to 24, as described above, the electronic component module 500 can be electrically connected to the printed circuit board 200 via the first cable 545 and the second cable 555. In this case, the coupling regions of the first cable 545 and the second cable 555 in the printed circuit board 200 may be one corner and another corner being disposed facing the one corner and the center of the printed circuit board 200, respectively.

As illustrated in FIG. 16, a plurality of the first cables 545 may be aligned through the first guide 570 and extended to a region being overlapped with a corner of the printed circuit board 200 in an up and down direction. In this case, the plurality of the first cables 545 may be aligned without being entangled with each other and having a constant gap between them through the first guide protrusion 574 of the first guide 570.

A shielding member 150 may be disposed between the cable 545 and the printed circuit board 200. The shielding member 150 is formed in a plate shape and may be disposed so as to be overlapped with a region in an up and down direction between one end of the first cable 545 being coupled with the electronic component module 500 and the other end of the first cable 545 being coupled with a connector 700, which will be described later. Accordingly, electrical noise may be prevented from occurring between the printed circuit board 200 and the first cable 545.

The power conversion device 10 may include a connector 700 for aligning a plurality of the first cables 545 and connecting them to the printed circuit board 200. The connector 700 may be disposed between the printed circuit board 200 and the cover 300. The connector 700 may be coupled to an upper surface of a bottom plate of the housing 100. The connector 700 may be screw-coupled to an upper surface of the bottom plate of the housing 100. In some cases, the connector 700 may be screw-coupled to an upper surface of the cover 300. The connector 700 may be disposed to be overlapped with at least a portion of the printed circuit board 200 in an up and down direction.

When the four corner areas of the printed circuit board 200 are respectively divided into a first corner, a second corner being disposed adjacent to the first corner, a third corner being disposed adjacent to the second corner, and a fourth corner being disposed adjacent to the first corner, the connector 700 may be disposed adjacent to the first corner, the electronic component module 500 may be disposed adjacent to the second corner, and the second cable 555 may be disposed adjacent to the third corner. In this case, the first cable 545 may be disposed to connect the first corner and the second corner.

The connector 700 may include a holder, a fastening portion 760, and a terminal portion 810.

The holder may form an outer shape of the connector 700. The holder may be screw-coupled to the bottom plate of the housing 100 or the upper surface of the cover 300. The holder may include a screw hole 705 for screw coupling. The screw holes 705 may be provided in multiple numbers and disposed to be spaced apart from one another.

The holder may include a first region 710, a second region 750, and a connection region 780 connecting the first region 710 and the second region 750. The holder may have a shape in which a guide portion 720 and a coupling portion 752, which will be described later, are disposed on a plate-shaped base 702. The holder may be formed of a plastic material.

With respect to a direction in which the first cable 755 is extended from the electronic component module 500, the first region 710 may be disposed at one end of the connector 700. The first region 710 may include a guide portion 720 being protruded upward from an upper surface of the base 702. The guide portion 720 may have a fence shape. The guide portion 720 may be provided in plurality and may be disposed to be spaced apart from one another with respect to the arrangement direction of the plurality of first cables 545. A cable coupling groove in which the first cables 545 are coupled may be formed between two adjacent guide portions 720.

When the first cable 545 are provided in six units and include a first-first cable, a first-second cable, a first-third cable, a first-fourth cable, a first-fifth cable, and a first-sixth cable, the cable coupling groove may include a first cable coupling groove 711 to which the first-first cable is coupled, a second cable coupling groove 712 to which the first-second cable is coupled, a first-third cable coupling groove 713 to which the first-third cable is coupled, a fourth cable coupling groove 714 to which the first-fourth cable is coupled, a fifth cable coupling groove 715 to which the first-fifth cable is coupled, and a sixth cable coupling groove 716 to which the first-sixth cable is coupled.

The cable coupling groove may have at least one bent region. Accordingly, the cable coupling groove may be divided into a plurality of regions. The plurality of regions of the cable coupling groove may be disposed perpendicularly to each other.

In order to firmly maintain the coupling state of the first cable 545 inside the cable coupling groove, the first region 710 may include a plurality of guide protrusions 722 and 724. The plurality of guide protrusions 722 and 724 may have a shape being protruded from a side surface of the guide portion 720. The guide protrusions 722 and 724 may come into contact with an outer surface of the first cable 545. The plurality of guide protrusions 722 and 724 may include a first guide protrusion 722 being disposed at one end of the cable coupling groove, and a second guide protrusion 724 being disposed between one end and the other end of the cable coupling groove. With respect to a single cable coupling groove, the guide portion 720 on which the first guide protrusion 722 is formed and the guide portion 720 on which the second guide protrusion 724 is formed may be different.

An extension portion 727 may be formed at the other end of the cable coupling groove facing the second region 750. The extension portion 727 may be formed to have a larger width than the other regions. The extension portion 727 may be formed at each cable coupling groove. In this case, adjacent extension portions 727 may be spaced apart from each other. The plurality of coupling grooves may be spaced apart from each other by the thickness of the guide portion 720 in a region where the guide protrusions 722 and 724 are formed, and may be spaced apart from each other more significantly in a region where the extension portion 727 is formed.

As illustrated in FIG. 22, a ring-shaped cable terminal 548 for coupling with the printed circuit board 200 may be formed at the end of the first cable 545. The cable terminal 548 may be formed to correspond to the cross-sectional shape of a coupling groove 754 in a coupling portion 752 to be described later. The cable terminal 548 may include a hole 549 through which a screw 900 to be described later penetrates. The diameter of the hole 549 of the cable terminal 548 may be formed to be larger than the diameter of a fastening region of the screw 900. The hole 549 of the cable terminal 548 may be referred to as a first hole. The cable terminal 548 may be formed of a metal material.

A covering region 547 having a larger cross-sectional area than other regions may be disposed on the outer surface of the first cable 545 adjacent to the cable terminal 548. The covering region 547 may be connected to the extension portion 727.

With respect to a direction in which the first cable 755 is extended from the electronic component module 500, the second region 750 may be disposed at the other end of the connector 700. The second region 750 may include a coupling portion 752 being protruded upward from an upper surface of the base 702. The coupling portion 752 may have a circular or oval cross-sectional shape with one side surface facing the first region 710 being open. The cable terminal 548 of the first cable 545 may be coupled to the coupling portion 752. A coupling groove 754 may be formed inside of the coupling portion 752 so that the cable terminal 548 may be coupled thereto.

An opening 751 may be formed on one side surface of the coupling portion 752. The first cable 545 may be disposed to penetrate through the opening 751. At least a portion of the covering region 547 or the cable terminal 548 may be disposed in the opening 751. The coupling portions 752 may be provided in multiple numbers corresponding to the number of the first cables 545. In this case, the multiple coupling portions 752 may be disposed in a zigzag shape. Accordingly, the ends of two adjacent coupling portions 752 among the multiple coupling portions 752 may have different distances from the first region 710. Accordingly, the size of the arrangement area of the multiple coupling portions 752 may become smaller.

The second region 750 may include a protrusion 756. The protrusion 756 may have a shape being protruded inwardly from an inner surface of the coupling portion 752. The protrusion 756 may be provided in plurality and may be disposed at each end of the coupling portion 752 adjacent to the opening 751. Through the protrusion 756, the coupling of the cable terminal 548 inside the coupling groove 754 may be primarily guided.

A protruded portion 757 (see FIG. 21) having a shape being protruded upwardly more than other regions may be formed on the bottom surface of the coupling groove 754 formed inside the coupling portion 752. The protruded portion 757 is for coupling the fastening portion 760 in which a groove 758 having a shape being recessed downwardly more than other regions may be formed on an upper surface thereof. The groove 758 may be formed in the center of the upper surface of the protruded portion 757.

The connection region 780 can connect the first region 710 and the second region 750. There may be no protruding configuration on the connection region 780. The covering region 547 can be disposed on the connection region 780. The second region 750 can be elastically supported with respect to the first region 710 through the connection region 780. Specifically, a downward pressing force can be generated during the screw coupling process between the fastening portion 760, the terminal portion 810, and the cable terminal 548 through the screw 900 described later. In this case, the pressing force can be offset by the elasticity of the second region 750 against the first region 710 through the connection region 780.

The fastening portion 760 may be disposed in the second region 750. The fastening portion 760 may be in contact with the coupling portion 760 and the cable terminal 548. The fastening portion 760 may be electrically connected to the cable terminal 548. The fastening portion 760 may be formed of a metal material and may be integrally formed with the holder by insert injection.

The fastening portion 760 may include a body 766 to which a groove 758 inside the coupling portion 752 is coupled, and a flange 764 being bent and extended outward from an upper end of the body 766. The body 766 may have a screw hole 762 formed in the center into which the screw 900 is screw-coupled. A screw thread or screw groove for screw coupling may be formed on an inner surface of the screw hole 762.

An upper surface of the flange 764 can support a lower surface of the cable terminal 548. The upper surface of the flange 764 and the lower surface of the cable terminal 548 can be in contact with each other. The contact area between the cable terminal 548 and the fastening portion 760 can be increased by the flange 764.

The terminal portion 810 may be disposed on a lower surface of the printed circuit board 200. The terminal portion 810 may be disposed between the cable terminal 548 and the printed circuit board 200. A terminal hole for coupling the terminal portion 810 may be formed in the printed circuit board 200. The terminal holes may be provided in multiple numbers corresponding to the number of the first cables 545. The terminal holes may have a shape penetrating from the upper surface to the lower surface of the printed circuit board. At least a portion of the terminal portion 810 may be coupled to the terminal hole.

The terminal portion 810 may be soldered to a lower surface of the printed circuit board 200. A circuit (pattern not shown) may be formed on a surface of the printed circuit board 200 to which the terminal portion 810 is coupled. By the contact between the terminal portion 810 and the cable terminal 548, the first cable 545 and the printed circuit board 200 may be electrically connected.

The terminal portion 810 may include a plurality of regions with different cross-sectional areas. The terminal portion 810 may include: an upper region 814 being coupled to the terminal hole; and a lower region 812 supporting a lower surface of the printed circuit board 200 and has the lower surface in contact with the cable terminal 548. The lower region 812 may be formed to have a larger cross-sectional area than the terminal hole or the upper region 814.

The terminal portion 810 may include a hole 815 through which the screw 900 penetrates. In this case, a screw thread or screw groove may not be formed in the hole 815. The hole 815 of the terminal portion 810 may be referred to as a second hole.

The screw 900 can be screw-coupled to the screw hole 762 of the fastening portion 760 by penetrating through the hole 815 of the terminal portion 810 and the hole 549 of the cable terminal 545. Since the screw 900 is screw-coupled only with the fastening portion 760, the second region 750 and the printed circuit board 200 can be pressed in a way that they come close to each other during the screw-coupling process of the screw 900 and the fastening portion 760.

Meanwhile, as described above, the assembly hole 290 can be formed in the printed circuit board 200, and the worker can check the assembly status of the printed circuit board 200, the cable terminal 548, and the terminal portion 810 through the assembly hole 290. According to the above described structure, there is an advantage in that multiple cables inside the device can be easily aligned by preventing them from being entangled or twisted with one another through the connector.

Especially, the buried structure through the cable coupling groove inside the connector has the advantage of improving assemblability and preventing the cable from being protruded into other regions inside the housing.

In addition, there is an advantage in that the coupling force in the electrical connection region can be maintained more firmly due to the increased contact area and the coupling structure among the cable terminal, fastening portion, and terminal portion that takes tension into account.

In the above description, it is described that all the components constituting the embodiments of the present invention are combined in one or operated in one by being combined, but the present invention is not necessarily limited to these embodiments. In other words, inside the scope of the present invention, all of the components may be selectively operated in combination with one or more. In addition, the terms “comprise”, “include” or “having” described above mean that the corresponding component may be inherent unless specifically stated otherwise, and thus it should be construed that it does not exclude other components, but further include other components instead. All terms, including technical and scientific terms, have the same meaning as commonly understood by one of ordinary skill in the art unless otherwise defined. Terms used generally, such as terms defined in a dictionary, should be interpreted to coincide with the contextual meaning of the related art, and shall not be interpreted in an ideal or excessively formal sense unless explicitly defined in the present invention.

The above description is merely illustrative of the technical idea of the present invention, and those skilled in the art to which the present invention pertains may make various modifications and changes without departing from the essential characteristics of the present invention. Therefore, the embodiments disclosed in the present invention are not intended to limit the technical idea of the present invention but to describe the present invention, and the scope of the technical idea of the present invention is not limited by these embodiments. The protection scope of the present invention should be interpreted by the following claims, and all technical ideas inside the equivalent scope should be interpreted as being included in the scope of the present invention.

1-10. (canceled)

11. A power conversion device comprising:
a housing;
a printed circuit board disposed inside the housing,
an electronic component module including a core and a plurality of cables extended from the core; and
a connector disposed on one surface of the printed circuit board and to which one end of a cable is coupled,
wherein a cable terminal is disposed at one end of each of the plurality of cables, and
wherein the connector includes:
a first region including a plurality of cable coupling grooves so that the plurality of cables is separately coupled to one another; and
a second region including a coupling portion and a coupling groove formed inside the coupling portion so that the cable terminals are coupled.

12. The power conversion device according to claim 11, wherein the connector includes a holder,
wherein multiple guide portions protruded upward are formed on an upper surface of the holder corresponding to the first region, and
wherein the cable coupling groove is disposed between the multiple guide portions.

13. The power conversion device according to claim 11, wherein the cable coupling groove have a region bent at least once.

14. The power conversion device according to claim 12, wherein a guide protrusion for supporting the cable is formed on a side surface of the guide portion, and
wherein the guide protrusion is respectively formed on one side surface of the guide portion and one side surface of an adjacent guide portion, with respect to a single cable coupling groove.

15. The power conversion device according to claim 11, wherein a covering region having a shape with a larger cross-sectional area than other regions is disposed on an outer surface of the cable adjacent to the cable terminal, and
wherein an extension portion having a larger width than other regions and to which the covering region is coupled is disposed at one end of the cable coupling groove facing the second region.

16. The power conversion device according to claim 11, wherein a plurality of coupling portions is provided in multiple numbers corresponding to the number of cables, and
wherein the plurality of coupling portions is disposed in a zigzag shape.

17. The power conversion device according to claim 11, including a connection region connecting the first region and the second region,
wherein the second region is flexibly supported against the first region with respect to the connection region.

18. The power conversion device according to claim 11, including a protruded portion protruded from the bottom surface,
wherein the protruded portion includes a groove, and
wherein a fastening portion coupled to the groove and in contact with the cable terminal is included.

19. The power conversion device according to claim 18, wherein the fastening portion includes a body coupled to the groove and a flange extended outwardly from an upper end of the body, and
wherein an upper surface of the flange comes into contact with a lower surface of the cable terminal.

20. The power conversion device according to claim 19, wherein a screw hole is formed on an upper surface of the body so that a screw is screw-coupled thereto.

21. The power conversion device according to claim 11, comprising a terminal portion arranged between the printed circuit board and the cable terminal,
wherein the terminal portion is in contact with the cable terminal.

22. The power conversion device according to claim 11, wherein the terminal portion includes a second hole through which a screw penetrates.

23. The power conversion device according to claim 22, wherein the terminal portion includes an upper region coupled to a terminal hole of the printed circuit board and a lower region supporting a lower surface of the printed circuit board,
wherein the lower region is in contact with the cable terminal, and
wherein a cross-sectional area of the lower region is larger than a cross-sectional area of the upper region or the terminal hole.

24. The power conversion device according to claim 21, wherein the terminal portion is soldered to a surface of the printed circuit board.

25. The power conversion device according to claim 11, wherein an opening is formed on one side of the coupling portion, and
wherein a protrusion is formed on an inner surface of the coupling portion adjacent to the opening to support the cable terminal.

26. A power conversion device comprising:
a housing;
a printed circuit board disposed inside the housing;
an electronic component module including a core and a plurality of cables extended from the core; and
a connector disposed on one surface of the printed circuit board and to which one end of a cable is coupled,
wherein the connector includes:
a first region including a plurality of cable coupling grooves so that the plurality of cables is separately coupled to one another,
a second region including a coupling portion and a coupling groove formed inside the coupling portion so that the cable terminals are coupled; and
a connection region connecting the first region and the second region,
wherein the second region is flexibly supported against the first region with respect to the connection region.

27. The power conversion device according to claim 26, wherein the connector includes a holder,
wherein multiple guide portions protruded upward are formed on an upper surface of the holder corresponding to the first region, and
wherein the cable coupling groove is disposed between the multiple guide portions.

28. The power conversion device according to claim 26, wherein the cable coupling groove have a region bent at least once.

29. The power conversion device according to claim 27, wherein a guide protrusion for supporting the cable is formed on a side surface of the guide portion, and
wherein the guide protrusion is respectively formed on one side surface of the guide portion and one side surface of an adjacent guide portion, with respect to a single cable coupling groove.

30. The power conversion device according to claim 26, wherein a plurality of coupling portions is provided in multiple numbers corresponding to the number of cables, and
wherein the plurality of coupling portions is disposed in a zigzag shape.
